(19) United States
(12) Patent Application Publication
(10) Pub. No.: US 2024/0079278 A1
(43) Pub. Date: Mar. 7, 2024

(54) Well Modulation for Defect Inspection

(71) Applicant: Taiwan Semiconductor Manufacturing Co., Ltd., Hsinchu (TW)

(72) Inventors: Jhih-Yong Han, Douliu City (TW); Wen-Yen Chen, Hsinchu (TW); Yi-Ting Wu, Taoyuan City (TW); Tsai-Yu Huang, Taoyuan City (TW); Huicheng Chang, Tainan City (TW); Yee-Chia Yeo, Hsinchu (TW)

(21) Appl. No.: 18/151,061

(22) Filed: Jan. 6, 2023

Related U.S. Application Data
(60) Provisional application No. 63/386,114, filed on Dec. 5, 2022.
(60) Provisional application No. 63/374,790, filed on Sep. 7, 2022.

(51) Int. Cl. H01L 21/8238; H01L 27/092

(52) U.S. Cl. CPC H01L 21/823892; H01L 21/823807; H01L 21/823821; H01L 27/0924; H01L 27/0928; H01L 21/266

(57) ABSTRACT

A method includes forming a pad layer. The pad layer includes a first portion over a first part of a semiconductor substrate, and a second portion over a second part of the semiconductor substrate. The first portion has a first thickness, and the second portion has a second thickness smaller than the first thickness. The semiconductor substrate is then annealed to form a first oxide layer over the first part of the semiconductor substrate, and a second oxide layer over the second part of the semiconductor substrate. The pad layer, the first oxide layer, and the second oxide layer are removed. A semiconductor layer is epitaxially grown over and contacting the first part and the second part of the semiconductor substrate.

### PRIORITY CLAIM AND CROSS-REFERENCE

This application claims the benefit of the U.S. Provisional Application No. 63/386,114, filed on Dec. 5, 2022, and entitled Well Modulation for Defect Inspection,” and Provisional Application No. 63/374,790, filed on Sep. 7, 2022, and entitled “Method of Modulation in Well Anneal for Defect Inspection,” which applications are hereby incorporated herein by reference.

### BACKGROUND

In the formation of integrated circuits, n-well regions and p-well regions are formed, and may join to each other. The n-well regions and p-well regions are formed by implanting n-type impurities and n-type impurities, respectively, into semiconductor substrates. Integrated circuit devices such as transistors are formed based on the wells and p-well regions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7, 8A, 8B, 9A, 9B, 10-11, and 12A illustrate the cross-sectional views of intermediate stages in the well modulation processes and the formation of Gate-All-Around (GAA) transistors in accordance with some embodiments.

FIG. 12B illustrates a device region including a divot at a joining region of a p-well region and an n-well region in accordance with some embodiments.

FIGS. 13A, 13B, 14-18, and 19A illustrate the cross-sectional views of intermediate stages in the well modulation processes and the formation of Fin Field-Effect Transistors (FinFETs) in accordance with some embodiments.

FIG. 19B illustrates a device region including a divot at a joining region of a p-well region and an n-well region in accordance with some embodiments.

FIGS. 20 and 21 illustrate Atomic Force Microscope (AFM) images of alternating p-well regions and n-well regions in accordance with some embodiments.

FIG. 22 illustrates a process flow for well modulation processes and the formation of GAA transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of modulating the top surface levels of p-well regions and n-well regions is provided. In accordance with some embodiments of the present disclosure, a pad oxide layer is formed over a semiconductor substrate. An n-well region and a p-well region are then formed, and join to each other. A well anneal process is then performed, with the process gas for the well anneal process including oxygen. The pad oxide layer over the n-well region is made thinner than the portion of the pad oxide layer over the n-well region. Accordingly, in the well anneal process, a thicker surface portion of the n-well region is oxidized than the oxidized surface portion of the p-well region. After oxide layers are removed, there is a step height between the top surfaces of the remaining p-well region and n-well region. The step height may be used to distinguish the p-well region from the n-well region, and to help to determine the positions of defects.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

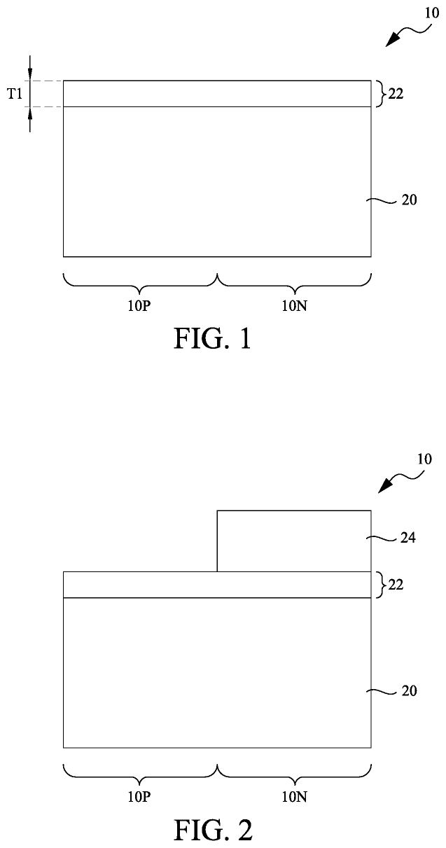

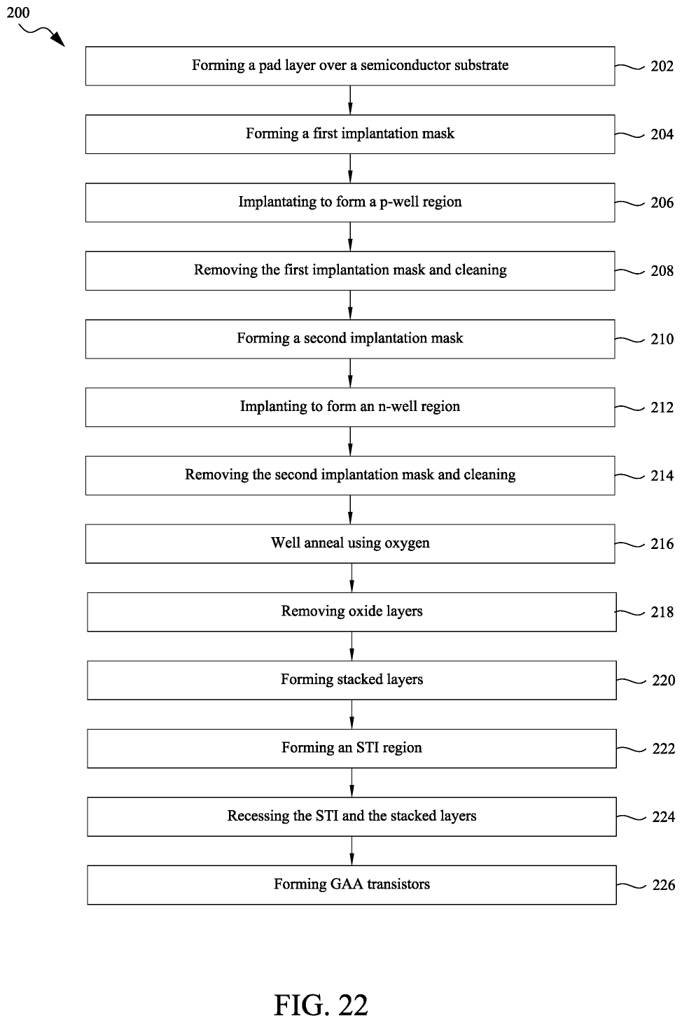

FIGS. 1-7, 8A, 8B, 9A, 9B, 10-11, and 12A illustrate the cross-sectional views of intermediate stages in the formation of well regions having step heights, and the formation of Gate-All-Around (GAA) transistors in accordance with some embodiments of the present disclosure. The corresponding processes are also reflected schematically in the process flow shown in FIG. 22.

In FIG. 1, wafer 10, which includes substrate 20, is provided. Wafer 10 also includes device region 10P, in which a p-well region is to be formed, and an n-well region, in which an n-well region is to be formed. Substrate 20 may be a semiconductor substrate, such as a bulk semiconductor substrate, a Semiconductor-On-Insulator (SOI) substrate, or the like, which may be doped (e.g., with a p-type or an n-type dopant) or undoped. Other substrates such as a multi-layered or gradient substrate may also be used. In some embodiments, the semiconductor material of semiconductor substrate 20 may include silicon; germanium; a compound semiconductor including carbon-doped silicon, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof.

Pad layer 22 is formed on semiconductor substrate 20. The respective process is illustrated as process 202 in the process flow 200 as shown in FIG. 22. Pad layer 22 may be a thin film formed of or comprising silicon oxide, and accordingly is alternatively referred to as pad oxide layer 22 hereinafter. Pad oxide layer 22 may act as an implantation buffer layer in subsequent formation of well regions, and may also be used in well anneal processes to modulate the heights of well regions, as will be discussed in subsequent paragraphs. In accordance with alternative embodiments, pad oxide layer 22 may be formed of other materials other than silicon oxide, and may be formed of or comprising silicon oxynitride, silicon oxycarbide, or the like. Pad layer 22 may also be formed of or comprise other materials other than oxide such as silicon carbide, silicon carbo-nitride, or the like.

In accordance with some embodiments of the present disclosure, pad oxide layer 22 is formed in a thermal oxidation process, wherein a top surface layer of semiconductor substrate 20 is oxidized to form pad oxide layer 22. In accordance with alternative embodiments of the present disclosure, pad oxide layer 22 is formed through a deposition process. The deposition process may be achieved through Chemical Vapor Deposition (CVD), Plasma Enhance Chemical Vapor Deposition (PECVD), Atomic Layer Deposition (ALD), or the like. In accordance with some embodiments, the thickness T1 of pad oxide layer 22 is in the range between about 3 nm and about 9 nm, and may be in the range between about 4 nm and about 8 nm.

Referring to FIG. 2, implantation mask 24 is formed and patterned. The respective process is illustrated as process 204 in the process flow 200 as shown in FIG. 22. Implantation mask 24 may be a single-layer mask including a photoresist, a dual-layer mask including a photoresist and a Bottom Anti-Reflective Coating (BARC) underlying the photoresist, or a tri-layer including a bottom layer including a cross-linked photoresist, an inorganic middle layer, and a top layer that includes a photoresist. As a result of the patterning process, the portion of implantation mask 24 over device region 10P of wafer 10 is removed, while the portion of implantation mask 24 over device region 10N of wafer 10 remains. The patterning process may include a light-exposure process followed by a development process.

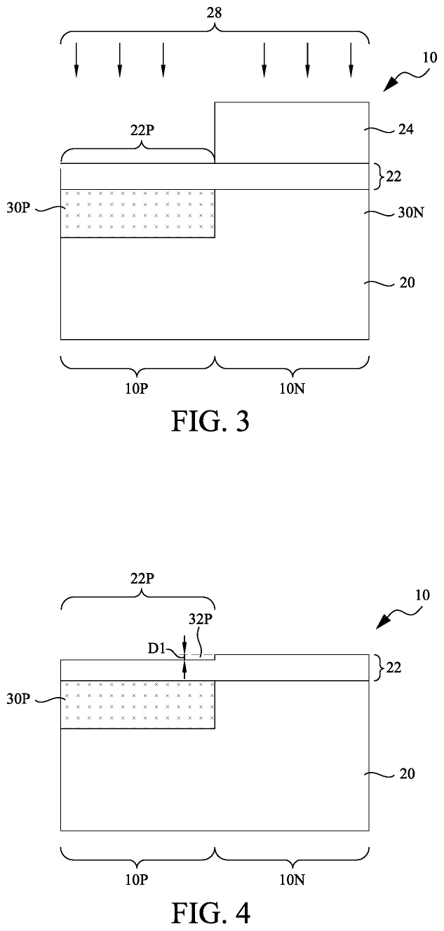

Referring to FIG. 3, implantation process 28 is performed. The respective process is illustrated as process 206 in the process flow 200 as shown in FIG. 22. The portions of semiconductor substrate 20 in device region 10P is implanted with a p-type dopant(s) to form p-well region 30P. The p-type dopant may include boron, indium, or the like. In accordance with some embodiments, implantation process 28 includes a plurality of implantation processes performed using different energies (for example, in the range between about 1 keV and about 500 keV), so that p-well region 30P may have a desirable depth and a desirable distribution. For example, implantation process 28 may include a first implantation process using an energy between about 40 keV and about 50 keV, a second implantation process using an energy between about 18 keV and about 22 keV, a third implantation process using an energy between about 12.5 keV and about 17.5 keV, a fourth implantation process using an energy between about 3 keV and about 8 keV, and a fifth implantation process using an energy between about 1.5 keV and about 3 keV. The total dosage of the p-type dopant in implantation process 28 may be in the range between about 1E13 atoms/cm² and about 5E15 atoms/cm².

Also, carbon may be implanted to retard the diffusion of the p-type dopant. The implantation of carbon may include a first implantation process using an energy in the range between about 10 keV and about 30 keV, and a second implantation process using an energy in the range between about 1.5 keV and about 5 keV.

After the formation of p-well region 30P, the remaining portion of implantation mask 24 is removed. The respective process is illustrated as process 208 in the process flow 200 as shown in FIG. 22. The resulting structure is shown in FIG. 4. The chemicals for removing implantation mask 24 are selected depending from the material of implantation mask 24. In accordance with some embodiments, diluted HF solution may be among the chemicals. Also, a cleaning process may be performed. The chemicals for the cleaning process may include the mixture of NH₄OH, H₂O₂, and H₂O, the mixture of sulfuric acid and hydrogen peroxide, the ozone (O₃) dissolved in water, or the like.

The pad oxide portion 22P of pad oxide layer 22 in device region 10P is exposed to the chemicals for removing implantation mask 24 and the chemicals for the cleaning process. The exposure time is also longer than the exposure time of pad oxide portion 22N to the chemicals, wherein pad oxide portion 22N is the portion of pad oxide layer 22 in device region 10N. As a result, the top surface of pad oxide portion 22P is recessed slightly to form recess 32P. The depth D1 of recess 32P may be in the range between about 0.1 nm and about 3 nm.

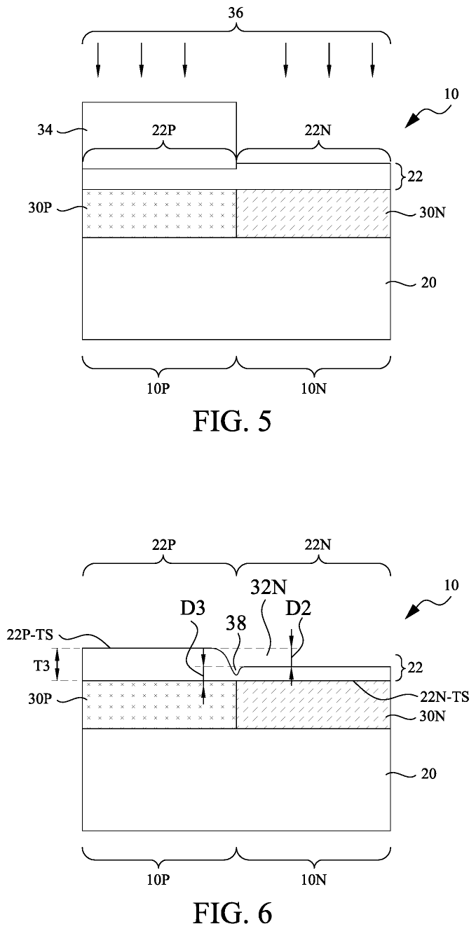

Referring to FIG. 5, implantation mask 34 is formed and patterned. The respective process is illustrated as process 210 in the process flow 200 as shown in FIG. 22. Implantation mask 34 may also be a single-layer mask, a dual-layer mask, a tri-layer mask, or the like, After the patterning process, the portion of implantation mask 34 over device region 10N is removed, while the portion of implantation mask 34 over device region 10P remains.

Further referring to FIG. 5, implantation process 36 is performed. The respective process is illustrated as process 212 in the process flow 200 as shown in FIG. 22. The portions of semiconductor substrate 20 in device region 10N is implanted with an n-type dopant(s) to form n-well region 30N. The n-type dopant may include phosphorous, arsenic, antimony, and/or the like. In accordance with some embodiments, implantation process 36 further includes a plurality of implantation processes performed using different energies (for example, in the range between about 1 keV and about 500 keV), so that n-well region 30N may have a desirable depth and a desirable distribution. For example, implantation process 36 may include a first implantation process using an energy between about 100 keV and about 150 keV, a second implantation process using an energy between about 40 keV and about 60 keV, a third implantation process using an energy between about 30 keV and about 40 keV, a fourth implantation process using an energy between about 20 keV and about 30 keV, and a fifth implantation process using an energy between about 5 keV and about 15 keV. The total dosage of the n-type dopant in implantation process 36 may be in the range between about 1E13 atoms/cm² and about 5E15 atoms/cm².

Also, carbon may be implanted to retard the diffusion of the n-type dopant and the neighboring p-type dopant. The energy for implanting carbon may be in the range between about 30 keV and about 50 keV.

After the formation of n-well region 30N, the remaining portion of implantation mask 34 is removed. The respective process is illustrated as process 214 in the process flow 200 as shown in FIG. 22. The resulting structure is shown in FIG. 6. The chemicals for removing implantation mask 34 may be similar to the chemicals for removing implantation mask 24, and is not repeated herein.

Pad oxide portion 22N is also exposed to the chemicals for removing implantation mask 34. Accordingly, in the removal of implantation mask 34, pad oxide portion 22N is also recessed. Also, pad oxide portion 22P is doped with the implanted p-type dopant, and pad oxide portion 22N is doped with the implanted n-type dopant. The difference in dopants may result in the etching rates of pad oxide portions 22P and 22N to be different from each other in the respective implantation mask removal and cleaning processes. In accordance with some embodiments, the top surface 22N-TS of pad oxide portion 22N is recessed more than the top surface 22P-TS of pad oxide portion 22P to form recess 32N. Recess 32N has depth D2, which is also the step height between the top surfaces 22N-TS and 22P-TS. In accordance with some embodiments, step height D2 is in the range between about 0.1 nm and about 3 nm. Also, ratio D2/T3 may be in the range between about 0.02 and about 0.5, wherein thickness T3 is the thickness of pad oxide portion 22P.

In accordance with some embodiments, processes are adjusted to adjust step height D2 into a desirable range. Throughout the description, the removal of implantation mask 24 and the corresponding cleaning process are referred to as p-removal processes, and the corresponding chemicals used are referred to as p-process chemicals. The removal of implantation mask 34 and the corresponding cleaning process are referred to as n-removal processes, and the corresponding chemicals used are referred to as n-process chemicals. In accordance with some embodiments, the p-process chemicals are the same as the n-process chemicals, and step height D2 may fall into a desirable range due to the etching rate difference in the etching of p-type doped pad oxide portion 22P and n-type doped pad oxide portion 22N.

In accordance with alternative embodiments, the p-process chemicals are adjusted to be different from the n-process chemicals to further increase or reduce step height D2 into the desirable range. In accordance with yet alternative embodiments, the p-process chemicals and the n-process chemicals include the same types of chemicals, while the concentrations/flow rates of the p-process chemicals and the n-process chemicals are different from each other. Also, process conditions may be adjusted so that the step height D2 may be adjusted (increased or reduced) to the desirable range. For example, the duration of the n-removal processes may be longer than, equal to, or shorter than the duration of the p-removal processes, and/or the wafer temperature (and/or the temperature of the n-process chemicals) in the n-removal processes may be higher than, equal to, or lower than the wafer temperature (and/or the temperature of the p-process chemicals) in the p-removal processes.

In accordance with alternative embodiments, instead of having the top surface of pad oxide portion 22N to be lower than the top surface of pad oxide portion 22P, the top surface of pad oxide portion 22N is adjusted to be higher than the top surface of pad oxide portion 22P. This may be achieved by adjusting the chemicals and/or the process conditions of the p-removal processes and the n-removal processes, as discussed above. For example, when proper p-process chemicals and n-process chemicals are selected, the etching rage of pad oxide portion 22P may be higher than the etching rate of pad oxide portions 22N. As a result, pad oxide portion 22P is thinner than, rather than thicker than, pad oxide portion 22N, and a step height is also formed. The corresponding step height may also be in the same range as discussed above.

Further referring to FIG. 6, due to the implantation mask removal processes and cleaning processes, groove 38 may be formed overlapping the joining region of pad oxide portion 22P and pad oxide portion 22N. Groove 38 may have a depth D3 in the range between about 0.1 nm and about 3 nm. Groove 38 may be tapered, with upper portions wider than respective lower portions.

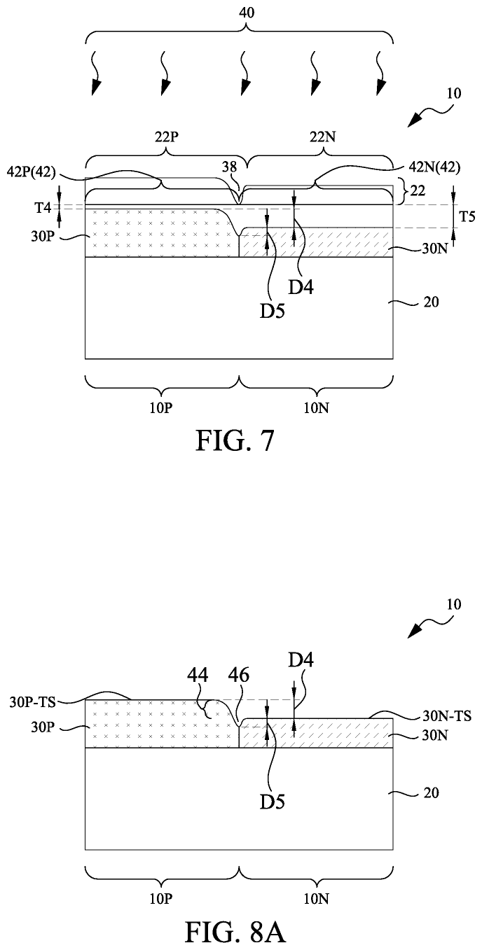

Referring to FIG. 7, well anneal process 40 is performed to anneal p-well regions 30P and n-well region 30N. The respective process is illustrated as process 216 in the process flow 200 as shown in FIG. 22. In accordance with some embodiments, well anneal process 40 is performed using Rapid Thermal Anneal (RTA), flash anneal, furnace anneal, or the like. The temperature of well anneal process 40 cannot be too high or too low. For example, if the wafer temperature is too low such as lower than about 1,000° C., the dopant activation may not be sufficient. If the wafer temperature is too high, for example, higher than about 1,200° C., due to excess diffusion of the dopant, the well isolation of p-well regions 30P from n-well region 30N may fail. Accordingly, the wafer temperature during the well anneal process 40 may be higher than about 1,000° C. in order to sufficiently activate the implanted dopants in p-well regions 30P and n-well region 30N, and may be in the range between about 1,000° C. and about 1,200° C.

Also, the duration of well anneal process 40 cannot be too short or too long. If the duration is too short, for example, shorter than about 0.1 seconds, the dopant activation may not be sufficient and the damage of the lattice structure caused by implantation may not be recovered. If the duration is too long, for example, longer than about 500 seconds, due to excess diffusion of the dopant, the well isolation may fail. Accordingly, the duration of well anneal process 40 may be in the range between about 0.1 seconds and about 500 seconds.

The ramp-up rate of the wafer temperature in well anneal process 40 also cannot be too low or too high. If the ramp-up rate is too low, for example, lower than about 25° C./second, defects such as clustering-induced nanosheet epitaxy defects may be resulted in subsequent processes. The ramp-up rate may also be selected to be greater than about 150° C./second to further reduce the implantation-induced damage of the well regions. The ramp-up rate may also be limited by the system limit of the annealing apparatus. For example, the system limit may be about 400° C./second. Accordingly, the ramp-up rate of well anneal process 40 may be in the range between about 25° C./second and about 400° C./second.

In the well anneal process 40, process gases such as hydrogen (H 2), nitrogen (N 2), argon, or the like, may be used as parts of the process gases. Furthermore, an oxygen-containing gas(es) such as O₂, N₂O, H₂O, or the like, or combinations thereof may be included in the process gases. The oxygen-containing gas results in the oxidation of the surface layers of p-well region 30P and n-well region 30N, so that oxide layers 42P and 42N are formed. Oxide layers 42P and 42N are parts of oxide layer 42. Oxide layers 42P and 42N may be, or may comprise, silicon oxide when semiconductor substrate 20 is or comprises silicon. Furthermore, oxide layers 42P and 42N may include the dopant doped into the respective well regions 30P and 30N, respectively.

The thickness T4 of the oxide layer 42P and thickness T5 of 42N are affected by the thicknesses of pad oxide portions 22P and 22N. Thicker pad oxide portion results in slower penetration of oxygen, and hence the respective underlying oxide layer is thinner, and vice versa. Accordingly, thickness T4 may be smaller than thickness T5. In accordance with some embodiments, the difference (T5−T4) is in the range between about 0.1 nm and about 3 nm, and may be in the range between about 0.5 nm and about 1.5 nm. In accordance with alternative embodiments in which pad oxide portion 22N is thicker than pad oxide portion 22P, thickness T4 will be greater than thickness T5.

Also, as shown in FIG. 7, oxide layer 42 includes a portion, which is the joining portion of oxide layers 42N and 42P. The joining portion extends lower than the bottom surfaces of both of oxide layers 42N and 42P to form a downward protrusion. In accordance with some embodiments, the depth of the protrusion is greater than about 0.1 nm, and may be in the range between about 0.1 nm and about 3 nm.

Also, the top surfaces of the remaining p-well region 30P and n-well region 30N have step height D4. The value of step height D4 is selected based on the compromising of various factors. For example, a small step depth D4 is advantageous for the subsequent epitaxy process, and may lead to the reduction in the defect density in the subsequently formed epitaxy layers. The small step height D4, however, may lead to reduced contrast in the p-well patterns and n-well patterns, as will be discussed subsequently. A high step depth D4, on the other hand, may lead to improved contrast in the p-well patterns and n-well patterns, but a higher step depth D4 also leads to a higher defect density. Accordingly, the step height D4 is designed to be in a range that is not too high and not too low. For example, step height D4 may be in the range between about 0.1 nm and about 3 nm. Also, step height D4 may be higher than about 1 nm for enhanced contrast.

The concentration (referred to as oxygen concentration hereinafter) of the oxygen-containing process gas may be adjusted to adjust the thicknesses of oxide layers 42P and 42N, and to modulate step height D4. The oxygen concentration cannot be too low or too high. If the oxygen concentration is too low, for example, lower than about 1 part-per-million (ppm), oxide layers 42P and 42N may comprise silicon monoxide rather than silicon dioxide, and after the removal of oxide layers 42P and 42N, the surface roughness of p-well region 30P and n-well region 30N may be high. A low oxygen concentration may also result in step height D4 to be too small, and result in inadequate contrast between p-well regions and n-well regions, as will be discussed in subsequent paragraphs. If the oxygen concentration is too high, for example, higher than about 500 ppm, step height D4 will be too high, and the defect density in the subsequently formed epitaxy layers will be high. Accordingly, the oxygen concentration of well anneal process 40 may be in the range between about 1 ppm and about 500 ppm.

Also, the desirable oxygen concentration may be affected by design considerations. For example, if a high contrast is desirable, a high oxygen consideration (such as greater than 300 ppm) may be adopted. If, however, a low defect density in epitaxy layers has a higher priority than the contrast, a low oxygen consideration (such as lower than 300 ppm) may be adopted.

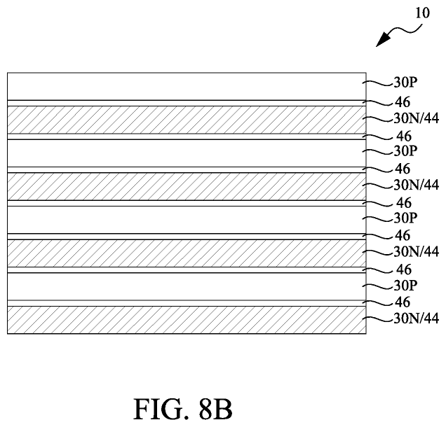

Pad oxide layer 22 and oxide layers 42P and 42N are then removed. The respective process is illustrated as process 218 in the process flow 200 as shown in FIG. 22. The resulting structure is shown in FIG. 8A. The removal may be performed through a wet etching process or a dry etching process. For example, when wet etching is adopted, diluted HF solution may be used. When dry etching is used, the mixture of NF 3 and NH 3 or the mixture of HF and NH 3 may be used. After the removal of the oxide layers, the top surface of n-well region 30N is lower than the top surface of p-well region 30P to form recess 44. Recess 44 has depth D4 that is also the step height D4, which is formed between the top surface 30P-TS of p-well region 30P and the top surface 30N-TS of n-well region 30N. Also, groove 46 is formed at the interface between p-well region 30P and n-well region 30N. Groove 46 may be tapered, with upper portions wider than respective lower portions.

FIG. 8B illustrates a top view of a portion of wafer 10, wherein p-well regions 30P and n-well regions 30N are formed alternatingly. The top view may be obtained using Atomic Force Microscope (AFM) as AFM images. The darkness levels of the illustrated surfaces reflect the relative heights (as in FIG. 8A) of the top surfaces of p-well regions 30P and n-well regions 30N, and darker surfaces are recessed from lighter surfaces. Accordingly, p-well region 30P, n-well region 30N, and grooves 46 may be distinguished from each other due to their different heights, and accordingly their different darkness levels.

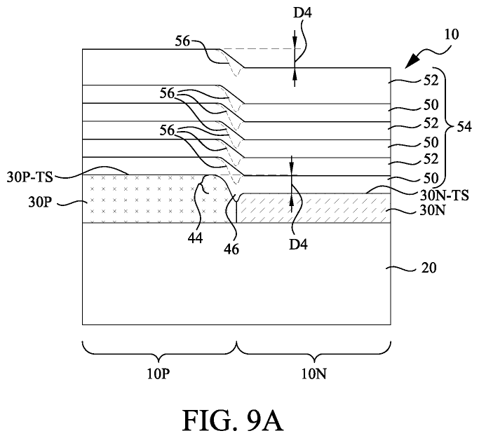

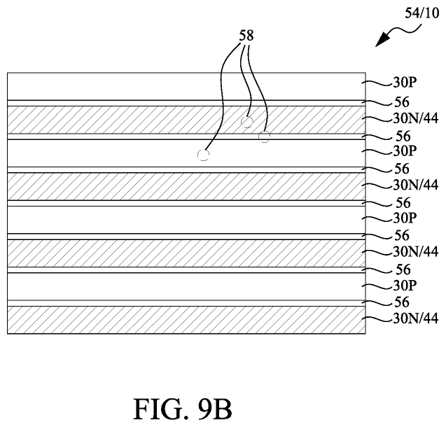

FIG. 9A illustrates the epitaxy of silicon germanium (SiGe) layers 50 and silicon layers 52, which are collectively referred to stacked layers 54. The respective process is illustrated as process 220 in the process flow 200 as shown in FIG. 22. SiGe layers 50 and silicon layers 52 are deposited alternatingly. The total thickness of the stacked layers 54 may be in the range between about 60 nm and about 90 nm. In accordance with some embodiments, SiGe layers 50 have germanium concentrations in the range between about 20 percent and about 40 percent. In accordance with some embodiments, groove 46 is filled by stacked layers 54, and the top surface of stacked layers 54 does not include the groove. In accordance with alternative embodiments, as shown by dashed lines, grooves 56 are also formed in stacked layers 54. The step height D4 is also formed in the top layer in stacked layers 54.

FIG. 9B illustrates a top view of a portion of wafer 10 after the formation of stacked layers 54. The top view may also be obtained using AFM. It is shown that due to step height D4, the portions of stack layers 54 directly over p-well region 30P and the portions of stack layers 54 directly over n-well region 30N may be clearly distinguished from each other due to their observable difference in darkness levels. In accordance with some embodiments in which grooves 56 are also formed, grooves 56 are also darker, and thus can also be distinguished from the portions of stacked layers 54 over p-well regions 30P and n-well regions 30N through the AFM image.

The defects of stacked layers 54 are then inspected. In the formation of stacked layers 54, defects may be formed. For example, FIG. 9B schematically illustrates some example defects 58. Defects 58 may include protrusions and/or recesses of stacked layers 54, which may be formed due to, for example, the falling of particles from the deposition chamber onto the epitaxy layers or other reasons.

It is appreciated that if step height D4 does not exist, or if step height D4 is not great enough, when a far Field Of View (FOV) of stacked layers 54 is obtained, wherein a large area of stacked layers 54 is observed through AFM, the portions of stack layers 54 directly over p-well region 30P and the portions of stack layers 54 directly over n-well region 30N may be distinguished from their darkness levels. The defects 58, however, cannot be viewed clear enough. Contrarily, when a near FOV of stacked layers 54 is obtained, wherein a small area of stacked layers 54 is observed through AFM, defects 58 can be clearly viewed. The portions of stack layers 54 directly over p-well region 30P and the portions of stack layers 54 directly over n-well region 30N, however, may not be distinguished.

In accordance with the embodiments of the present disclosure, by forming and increasing step height D4, both of the defects 58 and the portions of stack layers 54 directly over p-well regions 30P and n-well regions 30N may be clearly distinguished from each other. The positions of defects 58 (whether they are over p-well region 30P or n-well region 30N) can thus be determined to help the determination of the root cause of the defects.

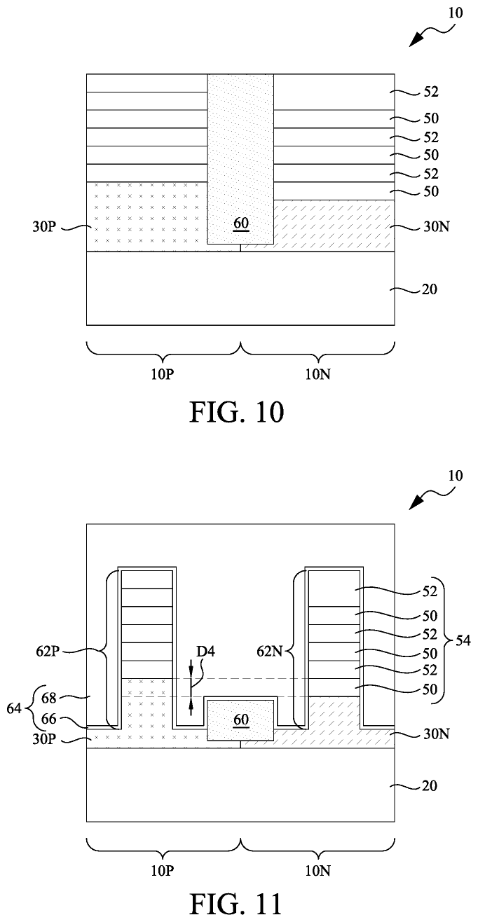

FIG. 10 illustrates the formation of isolation region 60, which may be a Shallow Trench Isolation (STI) region. The respective process is illustrated as process 222 in the process flow 200 as shown in FIG. 22. The formation process may include etching stacked layers 54, p-well region 30P, and n-well region 30N to form a trench, filling the trench with a dielectric material(s), and performing a planarization process to remove excess dielectric materials, so that STI region 60 is formed. STI region 60 may include silicon oxide, silicon nitride, and/or the like.

FIG. 11 illustrates the recessing of STI region 60. Also stacked layers 54, p-well region 30P, and n-well region 30N are recessed in accordance with some embodiments. The respective process is illustrated as process 224 in the process flow 200 as shown in FIG. 22. Accordingly, semiconductor strips 62P and 62N are formed.

Processes then proceed to the formation of an n-type GAA transistor and a p-type GAA transistor. The respective process is illustrated as process 226 in the process flow 200 as shown in FIG. 22. In accordance with some embodiments. Dummy gate stack 64, which may include dummy gate oxide 66 and dummy gate electrode 68, is formed. Gate spacers (not shown) are formed on the sidewalls of the dummy gate 64. Source/drain regions (not in the illustrated plane) are then formed, followed by the formation of a Contact Etch Stop Layer (CESL) and an Inter-Layer Dielectric (ILD) (not in the illustrated plane).

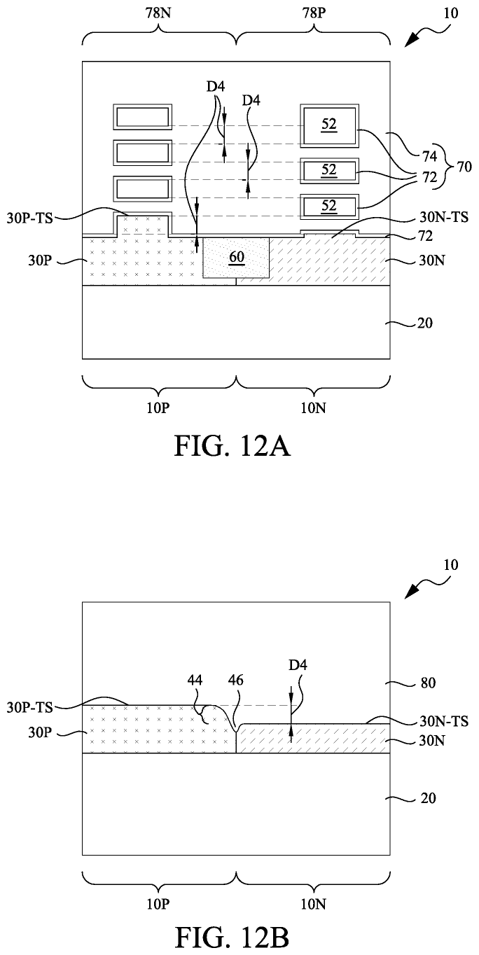

In a subsequent process, dummy gate stack 64 is removed, and SiGe layers 50 are removed. Referring to FIG. 12A, replacement gate stack 70, which includes replacement gate dielectrics 72 and replacement gate electrode 74, is then formed. N-type GAA transistor 78N and p-type GAA transistor 78P are thus formed, as shown in FIG. 12A.

FIG. 12B illustrates a cross-section that may be obtained from a different cross-section than the cross-section of FIG. 12A. The two cross-sections are obtained from a same device die in wafer 10. In accordance with some embodiments, in the illustrated device region, the groove 46 and step height D4 may exist in an integrated circuit device, which may be a p-n junction, a bipolar transistor, or the like. Structure 80 is formed over p-well region 30P and n-well region 30N. Structure 80 may include, and is not limited to, pickup regions, silicide regions, metal contacts, metal lines and vias, dielectric layers, and/or the like. The details of the structure 80 depend from the respective integrated circuit device, and are not shown. Also, the device region shown in FIG. 12B may also have a top view shape as shown in FIG. 8B, wherein p-well regions 30P and n-well regions 30N are allocated alternatingly, and have steps heights. Also, grooves 46 may also be formed between well regions 30P and n-well regions 30N.

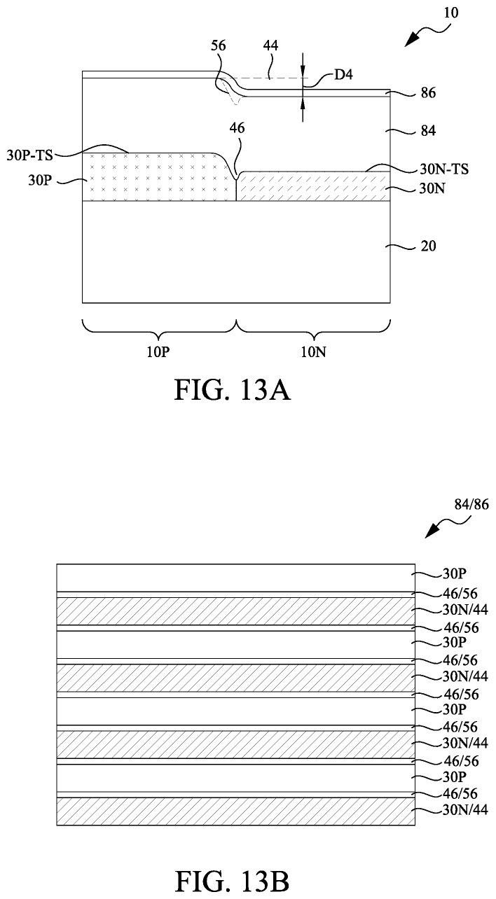

FIGS. 13A, 13B, 14-18, and 19A illustrate the cross-sectional views of intermediate stages in the formation of a Fin Field-Effect Transistor (FinFET) in accordance with alternative embodiments of the present disclosure. Unless specified otherwise, the materials, the structures, and the formation processes of the components in these embodiments are essentially the same as the like components denoted by like reference numerals in the preceding embodiments. The details regarding the materials, the structures, and the formation processes of the components shown in FIGS. 13A, 13B, 14-18, and 19A may thus be found in the discussion of the preceding embodiments.

The initial steps of these embodiments are essentially the same as shown in FIGS. 1-7, 8A, and 8B, in which p-well region 30P and n-well region 30N are formed, and step height D4 and groove 46 are generated. Next, as shown in FIG. 13A, semiconductor layer 84, which may be a silicon layer, is epitaxially grown on p-well region 30P and n-well region 30N. In the epitaxy of semiconductor layer 84, an n-type dopant such as phosphorous may be in-situ doped. Groove 56 may be, or may not be, formed at the top portion of semiconductor layer 84, depending on whether the epitaxy is performed through a conformal or non-conformal deposition process. Accordingly, groove 56 is shown using dashed lines. Next, hard mask 86 is deposited. Hard mask 86 may be formed of or comprise silicon oxide, silicon nitride, boron nitride, titanium nitride, or the like.

FIG. 13B illustrates a top view of semiconductor layer 84 and hard mask 86, wherein a plurality of p-well region 30P and n-well region 30N are formed as having an alternating pattern. Grooves 46 and 56 are also illustrated.

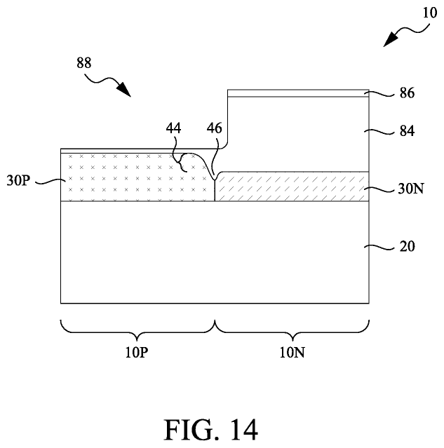

Referring to FIG. 14, semiconductor layer 84 is recessed to form recess 88. The formation process may include forming a patterned photoresist (not shown), and etching hard mask 86 and semiconductor layer 84 using the patterned photoresist as an etching mask. After the etching process, a thin semiconductor layer 84 may be left under recess 88. The patterned photoresist may then be removed.

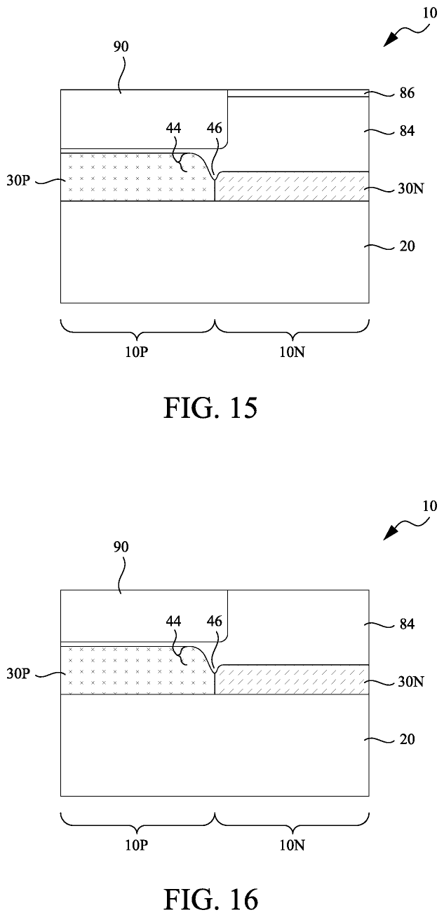

FIG. 15 illustrates the growth of semiconductor layer 90 through an epitaxy process. The material of semiconductor layer 90 is different from the material of semiconductor layer 84. For example, semiconductor layer 90 may include SiGe, with the germanium atomic percentage being in the range between about 20 percent and about 40 percent. In the epitaxy of semiconductor layer 90, a p-type dopant such as boron may be in-situ doped. The epitaxy may be selective, so that semiconductor layer 90 is grown from the exposed surface of semiconductor layer 84, and not from hard mask 86. After the epitaxy process, a planarization process such as a Chemical Mechanical Polish (CMP) process or a mechanical grinding process is performed to remove excess portions of semiconductor layer 90, leaving the semiconductor layer 90 as in FIG. 15.

In a subsequent process, hard mask 86 is removed, and the resulting structure is shown in FIG. 16.

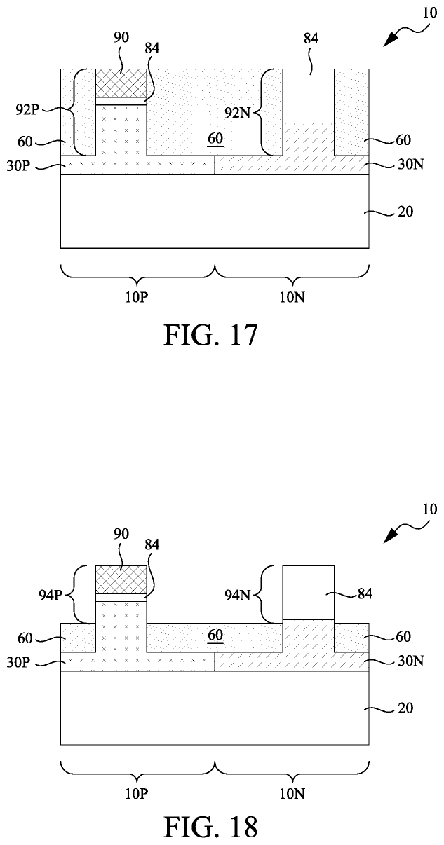

FIG. 17 illustrates the formation of STI regions 60. The formation process may include etching semiconductor substrate 20 to form trench, filling the trenches with a dielectric material(s), and performing a planarization process to remove excess dielectric materials, so that STI regions 60 are formed. Semiconductor strips 92P and 92N are formed. Semiconductor strip 92P includes a portion of p-well region 30P, a portion of semiconductor layer 84, and a portion of semiconductor layer 90. Semiconductor strip 92N includes a portion of n-well region 30N and a portion of semiconductor layer 84.

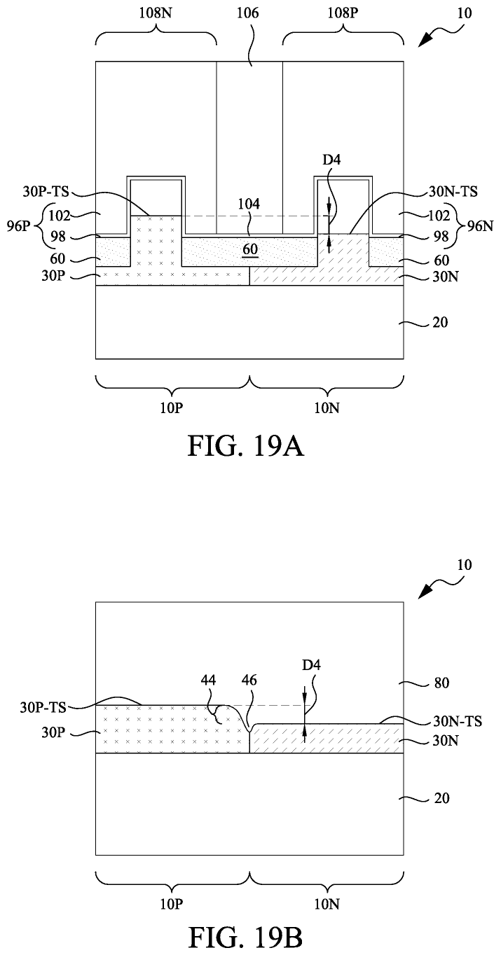

Processes then proceed to the formation of an n-type FinFET transistor and a p-type FinFET. Referring to FIG. 18, STI regions 60 are recessed, so that the top portions of semiconductor strips 92P and 92N are higher than the top surfaces of the remaining STI regions 60 to form protruding semiconductor fins 94P and 94N, respectively. A dummy gate(s) is formed on protruding semiconductor fins 94P and 94N. Source/drain regions (not shown) are then formed, followed by the formation of a CESL 104 and an ILD 106 (not shown in FIG. 18, refer to FIG. 19A) are formed.

In a subsequent process, the dummy gate stacks are removed. Replacement gate stacks 96P and 96N, which include replacement gate dielectrics 98 and replacement gate electrodes 102, are then formed. N-type FinFET 108N and p-type FinFET 108P are thus formed, as shown in FIG. 19A.

FIG. 19B also illustrates a cross-section that may be obtained from a different cross-section than the cross-section of FIG. 19A. The two cross-sections are obtained from a same die in wafer 10. In accordance with some embodiments, in the illustrated device region, the groove 46 and step height D4 may exist in an integrated circuit device, which may be a p-n junction, a bipolar transistor, or the like. Structure 80 is formed over p-well region 30P and n-well region 30N. Structure 80 may include, and is not limited to, pickup regions, silicide regions, metal contacts, metal lines and vias, dielectric layers, and/or the like. The details of the structure 80 depend from the respective integrated circuit device, and are not shown.

Also, the device region shown in FIG. 19B may have a top-view shape as shown in FIG. 8B, wherein p-well regions 30P and n-well regions 30N are allocated alternatingly, and have steps heights D4. Also, grooves 46 may also be formed between well regions 30P and n-well regions 30N.

In above-discussed example embodiments, the top surfaces of n-well regions 30N are recessed relative to the top surfaces of p-well regions 30P. In accordance with alternative embodiments, the top surfaces of n-well regions 30N may be higher than the top surfaces of p-well regions 30P. The corresponding step heights may be in the same range as step height D4. Accordingly, the top surfaces of n-well regions and p-well regions and the epitaxy layers formed thereon can be distinguished through their darkness levels also, although p-well regions 30P and the respective overlying portions of epitaxy layers may be darker than, rather than lighter than, n-well regions 30N and the respective overlying portions of epitaxy layers.

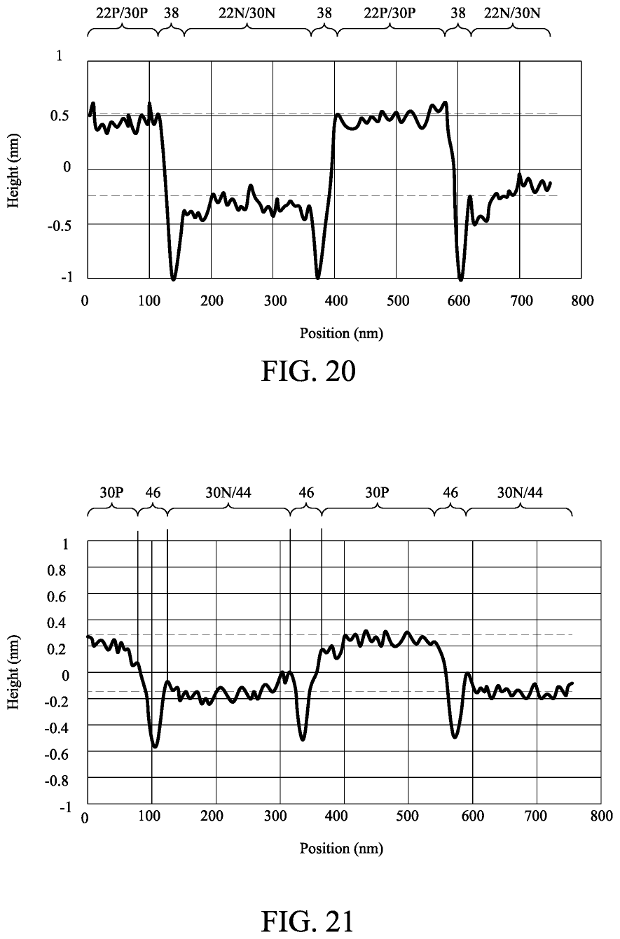

FIG. 20 illustrates the analysis of a sample having the structure shown in FIG. 6. The Y-axis represents the height of top surface of pad oxide layer 22. The X-axis represents the position traversing in a direction perpendicular to the interfaces of the p-well regions 30P and n-well regions 30N. As shown in FIG. 20, the top surfaces of pad oxide portions 22P are higher than the top surfaces of pad oxide portions 22N. Grooves 38 are also shown.

FIG. 21 illustrates the analysis of a sample having the structure shown in FIG. 8A. The Y-axis represents the top surfaces of p-well region 30P and n-well region 30N. The X-axis represents the position traversing in a direction perpendicular to the interfaces of p-well regions 30P and n-well regions 30N. As shown in FIG. 21, the top surfaces of p-well regions 30P are higher than the top surfaces of n-well regions 30N. Grooves 46 are also shown.

The embodiments of the present disclosure have some advantageous features. By adjusting the thicknesses of pad oxide portions, the respective underlying p-well regions and n-well regions are oxidized differently, and hence the top surfaces of the p-well regions and n-well regions have desirable step heights. When viewing the p-well region and n-well region from top through, for example, AFM image, the p-well regions and n-well regions can be distinguished from each other. The portions of epitaxy layer directly over the p-well regions and n-well regions can also be distinguished from each other, while the defects on the epitaxy layer can also be distinguished clearly. Accordingly, the positions of the defects relative to the p-well regions and n-well regions can be determined.

In accordance with some embodiments of the present disclosure, a method comprises forming a pad layer comprising a first portion over a first part of a semiconductor substrate, wherein the first portion has a first thickness; and a second portion over a second part of the semiconductor substrate, wherein the second portion has a second thickness smaller than the first thickness; annealing the semiconductor substrate to form a first oxide layer over the first part of the semiconductor substrate, and a second oxide layer over the second part of the semiconductor substrate; removing the pad layer, the first oxide layer, and the second oxide layer; and epitaxially growing a semiconductor layer over and contacting the first part and the second part of the semiconductor substrate.

In an embodiment, the method further comprises implanting the first part of the semiconductor substrate with a p-type dopant to form a p-well region, wherein the p-type dopant penetrates through the first portion of the pad layer; and implanting the second part of the semiconductor substrate with an n-type dopant to form an n-well region, wherein the n-type dopant penetrates through the second portion of the pad layer. In an embodiment, the second thickness is smaller than the first thickness by a difference in a range between about 0.1 nm and about 3 nm.

In an embodiment, the method further comprises, after the semiconductor layer is grown, inspecting the semiconductor layer using AFM image to determine positions of defects of the semiconductor layer. In an embodiment, the annealing is performed using a process gas comprising oxygen therein. In an embodiment, the annealing is performed when the pad layer covers the semiconductor substrate. In an embodiment, the method further comprises forming a first groove in the pad layer. In an embodiment, the method further comprises forming a second groove in the semiconductor substrate, wherein the second groove is in a joining region of the first part and the second part of the semiconductor substrate, and wherein the second groove is directly underlying the first groove. In an embodiment, the pad layer, the first oxide layer, and the second oxide layer comprise silicon oxide. In an embodiment, the first oxide layer and the second oxide layer are formed underlying the pad layer.

In accordance with some embodiments of the present disclosure, a structure comprises a semiconductor substrate; a first p-well region in the semiconductor substrate, wherein the first p-well region comprises a first top surface; and a first n-well region in the semiconductor substrate, wherein the first n-well region comprises a second top surface lower than the first top surface to form a step height, and wherein the first p-well region and the first n-well region join with each other to form a vertical interface. In an embodiment, the structure further comprises a dielectric isolation region extending into both of the first p-well region and the first n-well region, wherein the dielectric isolation region overlaps the vertical interface; a first plurality of semiconductor nanostructures overlapping the first p-well region; a first gate stack extending into gaps between the first plurality of semiconductor nanostructures; a second plurality of semiconductor nanostructures overlapping the first n-well region; and a second gate stack extending into gaps between the second plurality of semiconductor nanostructures.

In an embodiment, the structure further comprises a first semiconductor layer over and contacting the first p-well region; and a second semiconductor layer over and contacting the first n-well region. In an embodiment, the first semiconductor layer comprises a first silicon layer and a silicon germanium layer over and contacting the first silicon layer, and wherein the second semiconductor layer comprises a second silicon layer over and contacting the first n-well region. In an embodiment, the structure further comprises a second p-well region in the semiconductor substrate, wherein the second p-well region comprises a third top surface; and a second n-well region in the semiconductor substrate, wherein the second p-well region and the second n-well region join with each other to form an additional vertical interface, and wherein a groove is formed over and extending to the additional vertical interface. In an embodiment, the structure further comprises a plurality of p-well regions; and a plurality of n-well regions, each between and joining one of the plurality of p-well regions, wherein first top surfaces of the plurality of p-well regions are higher than second top surfaces of the plurality of n-well regions.

In accordance with some embodiments of the present disclosure, a structure comprises a semiconductor substrate; a plurality of p-well regions in the semiconductor substrate, wherein the plurality of p-well regions comprise first top surfaces; and a plurality of n-well regions in the semiconductor substrate, wherein the plurality of p-well regions and the plurality of n-well regions are allocated alternatingly, and wherein the plurality of n-well regions comprise second top surfaces lower than the first top surfaces; and a plurality of grooves, each between one of the plurality of p-well regions and one of the plurality of n-well regions, wherein the plurality of grooves extend down into corresponding ones of the plurality of p-well regions and the plurality of n-well regions, and bottoms of the plurality of grooves are lower than both of the first top surfaces and the second top surfaces. In an embodiment, each of the grooves is tapered, with upper portions wider than respective lower portions. In an embodiment, the plurality of p-well regions and the plurality of n-well regions form parallel strips in a top view of the structure. In an embodiment, the first top surfaces are coplanar with each other, and the second top surfaces are coplanar with each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a pad layer comprising:
a first portion over a first part of a semiconductor substrate, wherein the first portion has a first thickness; and
a second portion over a second part of the semiconductor substrate, wherein the second portion has a second thickness smaller than the first thickness;
annealing the semiconductor substrate to form a first oxide layer over the first part of the semiconductor substrate, and a second oxide layer over the second part of the semiconductor substrate;
removing the pad layer, the first oxide layer, and the second oxide layer; and
epitaxially growing a semiconductor layer over and contacting the first part and the second part of the semiconductor substrate.

2. The method of claim 1 further comprising:
implanting the first part of the semiconductor substrate with a p-type dopant to form a p-well region, wherein the p-type dopant penetrates through the first portion of the pad layer; and
implanting the second part of the semiconductor substrate with an n-type dopant to form an n-well region, wherein the n-type dopant penetrates through the second portion of the pad layer.

3. The method of claim 1, wherein the second thickness is smaller than the first thickness by a difference in a range between about 0.1 nm and about 3 nm.

4. The method of claim 1 further comprising, after the semiconductor layer is grown, inspecting the semiconductor layer using Atomic Force Microscope (AFM) image to determine positions of defects of the semiconductor layer.

5. The method of claim 1, wherein the annealing is performed using a process gas comprising oxygen therein.

6. The method of claim 1, wherein the annealing is performed when the pad layer covers the semiconductor substrate.

7. The method of claim 1 further comprising forming a first groove in the pad layer.

8. The method of claim 7 further comprising forming a second groove in the semiconductor substrate, wherein the second groove is in a joining region of the first part and the second part of the semiconductor substrate, and wherein the second groove is directly underlying the first groove.

9. The method of claim 1, wherein the pad layer, the first oxide layer, and the second oxide layer comprise silicon oxide.

10. The method of claim 1, wherein the first oxide layer and the second oxide layer are formed underlying the pad layer.

11. A structure comprising:
a semiconductor substrate;
a first p-well region in the semiconductor substrate, wherein the first p-well region comprises a first top surface; and
a first n-well region in the semiconductor substrate, wherein the first n-well region comprises a second top surface lower than the first top surface to form a step height, and wherein the first p-well region and the first n-well region join with each other to form a vertical interface.

12. The structure of claim 11 further comprising:
a dielectric isolation region extending into both of the first p-well region and the first n-well region, wherein the dielectric isolation region overlaps the vertical interface;
a first plurality of semiconductor nanostructures overlapping the first p-well region;
a first gate stack extending into gaps between the first plurality of semiconductor nanostructures;
a second plurality of semiconductor nanostructures overlapping the first n-well region; and
a second gate stack extending into gaps between the second plurality of semiconductor nanostructures.

13. The structure of claim 11 further comprising:
a first semiconductor layer over and contacting the first p-well region; and
a second semiconductor layer over and contacting the first n-well region.

14. The structure of claim 13, wherein the first semiconductor layer comprises a first silicon layer and a silicon germanium layer over and contacting the first silicon layer, and wherein the second semiconductor layer comprises a second silicon layer over and contacting the first n-well region.

15. The structure of claim 11 further comprising:
a second p-well region in the semiconductor substrate, wherein the second p-well region comprises a third top surface; and
a second n-well region in the semiconductor substrate, wherein the second p-well region and the second n-well region join with each other to form an additional vertical interface, and wherein a groove is formed over and extending to the additional vertical interface.

16. The structure of claim 11 further comprising:
a plurality of p-well regions; and
a plurality of n-well regions, each between and joining one of the plurality of p-well regions, wherein first top surfaces of the plurality of p-well regions are higher than second top surfaces of the plurality of n-well regions.

17. A structure comprising:
a semiconductor substrate;
a plurality of p-well regions in the semiconductor substrate, wherein the plurality of p-well regions comprise first top surfaces; and
a plurality of n-well regions in the semiconductor substrate, wherein the plurality of p-well regions and the plurality of n-well regions are allocated alternatingly, and wherein the plurality of n-well regions comprise second top surfaces lower than the first top surfaces; and
a plurality of grooves, each between one of the plurality of p-well regions and one of the plurality of n-well regions, wherein the plurality of grooves extend down into corresponding ones of the plurality of p-well regions and the plurality of n-well regions, and bottoms of the plurality of grooves are lower than both of the first top surfaces and the second top surfaces.

18. The structure of claim 17, wherein each of the grooves is tapered, with upper portions wider than respective lower portions.

19. The structure of claim 17, wherein the plurality of p-well regions and the plurality of n-well regions form parallel strips in a top view of the structure.

20. The structure of claim 17, wherein the first top surfaces are coplanar with each other, and the second top surfaces are coplanar with each other.
